(19) United States
(12) Patent Application Publication
(10) Pub. No.: US 2025/0253818 A1
(43) Pub. Date: Aug. 7, 2025

(54) JOSEPHSON JUNCTION TRAVELING-WAVE PARAMETRIC CIRCUITS WITH DISPERSIVE SIDEBAND SUPPRESSION

(71) Applicant: International Business Machines Corporation, Armonk, NY (US)

(72) Inventors: Corrado P. Mancini, Hopewell Junction, NY (US); Michael Karunendra Selvanayagam, Ossining, NY (US); Ruichen Zhao, Armonk, NY (US)

(21) Appl. No.: 18/429,593

(22) Filed: Feb. 1, 2024

(51) Int. Cl. H03F 19/00; G06N 10/00; H03F 7/02; H10N 60/12; H10N 60/80

(52) U.S. Cl. CPC H03F 19/00; G06N 10/00; H03F 7/02; H10N 60/12; H10N 60/805

(57) ABSTRACT

A device comprises a Josephson junction traveling-wave parametric circuit. The Josephson junction traveling-wave parametric circuit comprises unit cells which are coupled in series to form a transmission line between an input port and an output port. Each unit cell comprises a series Josephson junction, and a dispersive ground-shunt admittance configured to cause suppression of one or more sideband frequency components.

### BACKGROUND

This disclosure relates generally to quantum computing and, in particular, to quantum-limited amplifiers and frequency converters such as Josephson junctions traveling-wave parametric amplifiers and Josephson junctions traveling-wave frequency converters, for use with superconducting quantum computing systems. A superconducting quantum computing system is implemented using circuit quantum electrodynamics (QED) devices, which utilize the quantum dynamics of electromagnetic fields in superconducting circuits that include superconducting quantum bits, to generate and process quantum information. In general, superconducting quantum bits (qubits) are electronic circuits which are implemented using components such as superconducting tunnel junctions (e.g., Josephson junctions), inductors, and/or capacitors, etc., and which behave as quantum mechanical anharmonic (non-linear) oscillators with quantized states, when cooled to cryogenic temperatures.

The cryogenic hardware that is utilized to construct a quantum computer with superconducting qubits requires a variety of microwave components including microwave couplers, filters, amplifiers, circulators, and isolators. Traditionally, these components are implemented in qubit control and readout signal paths. A quantum limited amplifier (QLA) is typically implemented in a qubit readout signal path to amplify a readout signal from a qubit. A QLA is utilized to improve the signal-to-noise ratio in qubit measurements, thereby allowing higher fidelity qubit measurement and lower power qubit measurements (as higher measurement power correlates with higher qubit decoherence). Josephson parametric amplifiers have become a critical tool in superconducting device physics due to their high gain and quantum-limited noise. Traveling wave parametric amplifiers (TWPAs) promise similar noise performance while allowing for significant increases in both bandwidth and dynamic range.

A Josephson traveling-wave parametric amplifier (JTWPA) circuit is a type of superconducting QLA that is commonly implemented for quantum computing. In general, a JTWPA circuit comprises a nonlinear metamaterial transmission line comprising a series of Josephson junctions that provide the inductance for the transmission line as well as the non-linearity. The gain of a JTWPA circuit can be made exponential as a function of length by dispersion engineering the nonlinear transmission line for phase matching such that a longer JTWPA circuit provides more gain. The quantum efficiency of a JTWPA corresponds to a signal-to-noise ratio (SNR) of the quantum limited amplification process. The quantum efficiency of a JTWPA is based at least in part on noise contributions from the generation of undesired sideband frequency components (e.g., higher order intermodulation products) which result from parametric frequency mixing processes, wherein such sideband frequency components can reduce the quantum efficiency of the quantum limited amplification.

### SUMMARY

Exemplary embodiments of the disclosure include techniques for implementing Josephson junction traveling-wave parametric circuits, such as Josephson traveling-wave parametric amplifier circuits and Josephson traveling-wave frequency converter circuits, which implement unit cells with dispersive ground-shunt admittances for suppressing sideband frequency components.

For example, an exemplary embodiment includes a device which comprises a Josephson junction traveling-wave parametric circuit. The Josephson junction traveling-wave parametric circuit comprises unit cells which are coupled in series to form a transmission line between an input port and an output port. Each unit cell comprises a series Josephson junction, and a dispersive ground-shunt admittance configured to cause suppression of one or more sideband frequency components.

Advantageously, the implementation of a Josephson junction traveling-wave parametric circuit (e.g., JTWPA circuit) comprising unit cells with dispersive ground-shunt admittances enables the suppression of sideband frequency components. The dispersive ground-shunt admittances of the unit cells are configured to add dispersion along the transmission line of the Josephson junction traveling-wave parametric circuit to suppress and limit the generation of sideband frequency components (e.g., intermodulation frequency components). For example, in a JTWPA circuit, the dispersive ground-shunt admittances of the unit cells serve to increase the quantum efficiency and amplification gain of the JTWPA circuit by eliminating or otherwise reducing the coupling of signal mode to higher order sideband frequency components (e.g., higher order pump signal modes and intermodulation products).

In another exemplary embodiment, as may be combined with the preceding paragraphs, the Josephson junction traveling-wave parametric circuit comprises a Josephson traveling-wave frequency converter circuit.

In another exemplary embodiment, as may be combined with the preceding paragraphs, the Josephson junction traveling-wave parametric circuit comprises a Josephson traveling-wave parametric amplifier circuit.

In another exemplary embodiment, as may be combined with the preceding paragraphs, the dispersive ground-shunt admittance of each unit cell comprises a capacitive element and an inductive element. The inductive element is configured to add the dispersion along the transmission line to cause the suppression of the sideband frequency components.

In another exemplary embodiment, as may be combined with the preceding paragraphs, the capacitive element and the inductive element comprise a series-connected capacitor and inductor.

In another exemplary embodiment, as may be combined with the preceding paragraphs, the inductive element comprises a plurality of series-connected Josephson junctions.

In another exemplary embodiment, as may be combined with the preceding paragraphs, the Josephson junction traveling-wave parametric circuit further comprises dispersion resonators which are capacitively coupled to the transmission line and which are configured to maintain phase matching between different signal modes that are propagating along the transmission line.

Another exemplary embodiment includes a device which comprises a Josephson traveling-wave parametric amplifier circuit that is configured to amplify a readout signal representing a state of at least one quantum bit. The Josephson traveling-wave parametric amplifier circuit comprises unit cells which are coupled in series to form a transmission line between an input port and an output port. Each unit cell comprises a series Josephson junction, and a dispersive ground-shunt admittance configured to cause suppression of one or more sideband frequency components resulting from intermodulation between frequency components of the readout signal and a pump signal applied to the input port of the Josephson traveling-wave parametric amplifier circuit.

Another exemplary embodiment includes a system which comprises a quantum processor comprising quantum bits, and readout circuitry. The readout circuitry comprises at least one readout signal chain comprising a Josephson traveling-wave parametric amplifier circuit that is configured to amplify a readout signal representing a state of at least one quantum bit of the quantum processor. The Josephson traveling-wave parametric amplifier circuit comprises unit cells which are coupled in series to form a transmission line between an input port and an output port. Each unit cell comprises a series Josephson junction, and a dispersive ground-shunt admittance configured to cause suppression of one or more sideband frequency components resulting from intermodulation between frequency components of the readout signal and a pump signal applied to the input port of the Josephson traveling-wave parametric amplifier circuit.

Other embodiments will be described in the following detailed description of exemplary embodiments, which is to be read in conjunction with the accompanying figures.

### BRIEF DESCRIPTION OF THE DRAWINGS

FIG. 1 is a high-level schematic illustration of a Josephson junction traveling-wave parametric circuit which implements unit cells with dispersive ground-shunt admittances for suppressing sideband frequency components, according to an exemplary embodiment of the disclosure.

FIG. 2 is a high-level schematic illustration of a Josephson junction traveling-wave parametric circuit which implements unit cells with dispersive ground-shunt admittances for suppressing sideband frequency components, according to an exemplary embodiment of the disclosure.

FIG. 3 depicts simulated admittances of Josephson junction travelling-wave parametric circuits with and without the use of dispersive ground-shunt admittances in unit cells to suppress unwanted sideband frequency components, according to an exemplary embodiment of the disclosure.

FIG. 4A illustrates phase mismatching of sideband frequency components which results from implementing a Josephson junction traveling-wave parametric amplifier circuit having unit cells with dispersive ground-shunt admittances for suppressing sideband frequency components, according to an exemplary embodiment of the disclosure.

FIG. 4B illustrates simulated scattering parameter waveforms of a Josephson junction traveling-wave parametric amplifier circuit which implements unit cells with dispersive ground-shunt admittances for suppressing sideband frequency components, according to an exemplary embodiment of the disclosure.

FIG. 5A illustrates simulated signal gain waveforms of a Josephson junction traveling-wave parametric amplifier circuit having unit cells with different amounts of dispersion in the dispersive ground-shunt admittances for suppressing sideband frequency components, according to an exemplary embodiment of the disclosure.

FIG. 5B illustrates simulated plots of quantum efficiency of a Josephson junction traveling-wave parametric amplifier circuit having unit cells with different amounts of dispersion in the dispersive ground-shunt admittances for suppressing sideband frequency components, according to an exemplary embodiment of the disclosure.

FIG. 6 schematically illustrates readout circuitry of a quantum processing system in which Josephson traveling-wave parametric amplifier circuits are implemented in qubit readout signal paths to amplify qubit readout signals, according to an exemplary embodiment of the disclosure.

FIG. 7 schematically illustrates a quantum computing system, according to an exemplary embodiment of the disclosure.

FIG. 8 schematically illustrates an exemplary architecture of a computing environment for hosting a quantum computing platform and performing quantum information processing, according to an exemplary embodiment of the disclosure.

### DETAILED DESCRIPTION

Exemplary embodiments of the disclosure will now be described in further detail with regard to Josephson junction traveling-wave parametric circuits (JJTWPCs) which are configured to provide dispersive sideband suppression of intermodulation products. Exemplary embodiments of the disclosure include Josephson junction traveling-wave parametric circuits such as Josephson traveling-wave parametric amplifier (JTWPA) circuits/devices, and Josephson traveling-wave frequency converter (JTWFC) circuits/devices, wherein the JTWPA and JTWFC circuits are particular types of JJTWPCs. As explained in further detail below, techniques are provided for implementing Josephson junction traveling-wave parametric circuits with unit cells having dispersive ground-shunt admittances for suppressing sideband frequency components.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise quantum circuit elements (e.g., quantum processors, quantum bits, Josephson junction devices, Josephson parametric converters, quantum-limited amplifiers (QLAs), qubit coupler circuitry, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

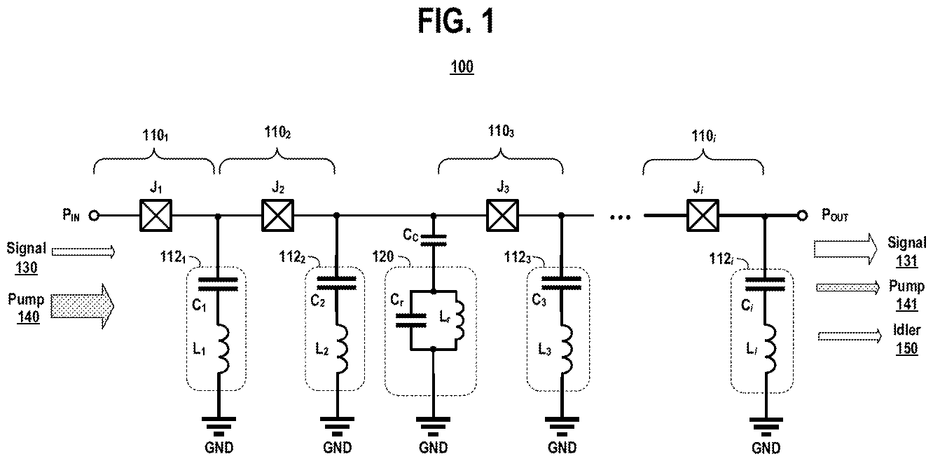

FIG. 1 is a high-level schematic illustration of a Josephson junction traveling-wave parametric circuit, according to an exemplary embodiment of the disclosure. In particular, FIG. 1 schematically illustrates an exemplary architecture of a Josephson traveling-wave parametric amplifier circuit 100 (or JTWPA circuit 100) which is configured to provide dispersive suppression of sideband frequency components (e.g., intermodulation products), according to an exemplary embodiment of the disclosure. The JTWPA circuit 100 comprises an input port P_{IN}, an output port POUT, and a non-linear transmission line comprising a series of unit cells 110₁, 110₂, 110₃, . . . , 110ᵢ (collectively, unit cells 110). Each unit cell 110₁, 110₂, 110₃, . . . , 110ᵢ of the non-linear transmission line comprises a respective Josephson junction J₁, J₂, J₃, . . . , Jᵢ, and a respective admittance 112₁, 112₂, 112₃, . . . , 112ᵢ which is shunted to ground GND (alternatively referred to as dispersive ground-shunt admittances 112₁, 112₂, 112₃, . . . , 112ᵢ). The Josephson junctions J₁, J₂, J₃, . . . , Jᵢ are connected in series between the input port Pix and the output port POUT.

In the exemplary embodiment, each dispersive ground-shunt admittance 112₁, 112₂, 112₃, . . . , 112ᵢ comprises a respective capacitive element C₁, C₂, C₃, . . . , Cᵢ, and a respective inductive element L₁, L₂, L₃, . . . , Lᵢ. In some embodiments, such as shown in FIG. 1, the dispersive ground-shunt admittances 112₁, 112₂, 112₃, . . . , 112ᵢ each comprise a series-connected capacitive element and inductive element. As explained in further detail below, the inductive elements Lᵢ, L₂, L₃, . . . , Lᵢ are configured to add dispersion along the transmission line to cause suppression of undesired sideband frequency components including, e.g., higher order harmonics of a pump signal and higher order intermodulation components, etc. In some embodiments, the capacitive and inductive elements of the dispersive ground-shunt admittances 112₁, 112₂, 112₃, . . . , 112ᵢ are implemented using lumped capacitors and inductors. In some embodiments, the dispersive ground-shunt admittances 112₁, 112₂, 112₃, . . . , 112ᵢ are implemented using a combination of lumped elements and distributed elements. For example, in some embodiments, each dispersive ground-shunt admittance 112₁, 112₂, 112₃, . . . , 112ᵢ is implemented using an electrically long interdigitated capacitor structure which comprises an effective series inductance with an equivalent circuit that would be similar to the component values chosen for a lumped inductor and capacitor. In other embodiments, each dispersive ground-shunt admittance 112₁, 112₂, 112₃, . . . , 112ᵢ is implemented using a dispersive transmission line.

In general, the JTWPA circuit 100 comprises a non-linear transmission line in which the Josephson junctions J₁, J₂, J₃, . . . , Jᵢ and the capacitive elements C₁, C₂, C₃, . . . , Cᵢ of the unit cells 110₁, 110₂, 110₃, . . . , 110ᵢ provide a non-linear inductance and linear capacitance per unit length, respectively, in the non-linear transmission line. The Josephson junctions J₁, J₂, J₃, . . . , Jᵢ comprise current dependent non-linear inductances. In some embodiments, the JTWPA circuit 100 comprises thousands of unit cells (e.g., thousands of series Josephson junction and dispersive ground-shunt admittances) to provide a sufficient electrical length to obtain a target gain (e.g., ˜ 20 dB of signal gain).

In an exemplary mode of operation of the JTWPA circuit 100 as shown in FIG. 1, an input signal 130 and a pump signal 140 are applied to the input port P_{IN}, and the JTWPA circuit 100 outputs plurality of signals from the output port Pour including an amplified output signal 131, an output pump signal 141, and an idler signal 150. The input signal 130 comprises a microwave signal (e.g., qubit readout signal) having a signal frequency fₛ (or angular frequency ωₛ=2πfₛ radians/second). The pump signal 140 comprises a microwave tone with a pump frequency fₚ (or angular frequency ωₚ=2πfₚ). The pump signal 140 provides power for amplifying the input signal 130 as the pump signal 140 and the input signal 130 traverse the length of the non-linear transmission line of the JTWPA circuit 100, thereby producing, e.g., the amplified output signal 131 and idler signal 150 (or idler tone) at the output port the output port Pour. The idler signal 150 comprises a microwave signal (or tone) with a frequency fᵢ (or angular frequency ωᵢ=2πfᵢ radians/second), which is generated as a result of a non-linear amplification process of the JTWPA circuit 100.

More specifically, the JTWPA circuit 100 is configured to provide a non-linear amplification of the input signal 130 by utilizing the pump signal 140 to modulate the Josephson potential of the Josephson junctions J₁, J₂, J₃, . . . , Jᵢ as the input signal 130 and the pump signal 140 propagate in the same direction over the non-linear transmission line of the JTWPA circuit 100. In particular, the pump signal 140 modulates the Josephson potential of the Josephson junctions J₁, J₂, J₃, . . . , Jᵢ to thereby perform a frequency mixing process (e.g., four-wave-mixing process) that leads to amplification of the input signal 130.

In some embodiments, the JTWPA circuit 100 is configured to perform a four-wave mixing process for amplification, in which energy from the pump signal 140 is coupled to the input signal 130 and the idler signal 150 is generated as a result of the four-wave mixing process such that ωₛ+ωᵢ=2ωₚ (or fₛ+fᵢ=2fₚ). In other words, for the four-wave mixing process, the idler signal 150 has a frequency fᵢ which is a function of the input signal frequency fₛ and the pump signal frequency fₚ as follows: fᵢ=2fₚ-fₛ (where, e.g.,

$${f}_{p} > \frac{{f}_{s}}{2} ) .$$

For example, in the four-wave mixing process for amplification, two pump photons of the pump signal 140 are converted into a new photon at the signal frequency fₛ and a new photon at the idler frequency fᵢ. This is schematically shown in FIG. 1, wherein the amplified output signal 131 is represented by an arrow which is thicker than an arrow which represents the input signal 130, and wherein the input pump signal 140 is represented by an arrow which is thicker than an arrow which represents the output pump signal 141.

As further schematically shown in FIG. 1, the JTWPA circuit 100 comprises a dispersion element 120 (e.g., dispersion resonator) which is configured to add dispersion along the transmission line so that energy and momentum can be simultaneously conserved during an amplification process. In some embodiments, as shown in FIG. 1, the dispersion element 120 comprises a microwave LC resonator circuit comprising a capacitor Cᵣ and inductor Lᵣ which are connected in parallel, and a coupling capacitor Ce which couples (e.g., “loosely” couples) the LC resonator to the non-linear transmission line of the JTWPA circuit 100. While FIG. 1 shows one dispersion element 120 for case of illustration, the JTWPA circuit 100 comprises multiple instances of the dispersion element 120 disposed at regular intervals (referred to as resonant phase matching (RPM) period) along the non-linear transmission line.

The dispersion elements (resonators) are configured to maintain phase matching to counteract the phase differences between the different modes (e.g., signal mode, pump mode, idler mode) that are propagating in the JTWPA circuit 100, and thereby increase the amplification gain. The term “RPM period” denotes a number of unit cells between dispersion resonators. For example, in some embodiments, every n^{th} unit cell (e.g., n=3) comprises an instance of the dispersion element 120. Typically, the dispersion elements 120 comprising the LC resonators and associated coupling capacitors Ce are designed to set a desired frequency range to obtain phase matching and counteract the dispersion along the transmission line of the JTWPA circuit 100. The use of dispersion engineering to achieve phase matching of the different modes propagating along the length of the transmission line of the JTWPA circuit 100 results in achieving exponential gain versus a length of the transmission line of the JTWPA circuit 100. In some embodiments, the dispersion elements 120 are implemented using lumped capacitor and inductor elements. In some embodiments, the dispersion elements 120 are implemented using transmission line resonators.

For the frequency mixing amplification process, both the energy (frequency) and momentum (wavevector) must be conserved in this process such that the following conditions are met: (i) 2ωₚ=ωᵢ+ωₛ, and (ii) 2kₚ=kᵢ+kₛ (or 2kₚ−kₛ−kᵢ=0), where kₚ denotes an angular wave vector of the pump mode, kₛ denotes an angular wave vector of the signal mode, and kᵢ denotes an angular wave vector of the signal mode. In general, the angular wave vector k describes how many radians a wave traverses per unit of distance, and has a magnitude (wavenumber) that is determined

$$\vert k \vert = \frac{2 π}{λ}$$

(with units of m 1) where A is the wavelength of the wave in a given medium. In wave propagation, dispersion in the phenomenon in which the phase velocity νₚ of a wave depends on its frequency as follows:

$${v}_{P} = \frac{λ}{T}$$

where T is a time period, and where

$$f = \frac{1}{T} .$$

Equivalently, in terms of the angular frequency ω and the wave number k, the phase velocity is determined as:

$${v}_{P} = \frac{ω}{k} .$$

For small signals, the above-noted conditions (i) and (ii) can be simultaneously satisfied. For relatively large pump frequencies, however, a non-linear phase shift is created such that the wave vector condition is no longer satisfied. To simultaneously satisfy both constraints, a resonant phase matching is provided by adding instances of the dispersion element 120 (e.g., dispersion resonator) periodically throughout the transmission line, which serves to alter the dispersion of the transmission line k(ω) such that both conditions (i) and (ii) are simultaneously satisfied for pump frequencies near the resonant frequency of the dispersion resonator.

While the dispersion elements 120 are configured to achieve a desired phase matching in the signal/idler/pump bands to enable efficient four-wave mixing for optimal gain performance, the quantum efficiency (e.g., SNR performance of the quantum limited amplification) of a JTWPA circuit is based primarily on internal efficiencies including (i) n_{D} which is set by a total loss along the length of the JTWPA circuit, and (ii) nⱼ which is set by noise contributions from the generation of undesired sideband frequency components as a result of frequency mixing processes generated in the JTWPA circuit. For instance, such sideband frequency components include harmonics of the pump frequency (e.g., 3fₚ) and higher order intermodulation products, such as f_{IM3}=2fₚ+fₛ, and f_{IM5}=4fₚ−fₛ, etc.

In a conventional JTWPA circuit, such undesired sideband frequency components are not inherently suppressed by the JTWPA circuit itself, and can be unintentionally enhanced. In particular, a conventional JTWPA circuit which comprises (i) a non-linear transmission line with unit cells that each comprise a series Josephson junction and shunt capacitor to ground, and (ii) dispersion resonators (coupled to the non-linear transmission line) to achieve phase matching of the signal/pump/idler modes, actually allows unwanted sideband frequency components to be generated as a result of similar frequency mixing processes (e.g., 4-wave mixing process) to that which amplifies the input signal. Consequently, in a conventional JTWPA circuit, the generation of such sideband frequency components is undesirable, as such sideband frequency components are sources of quantum noise that degrade the quantum efficiency of the JTWPA circuit.

To suppress the generation of such unwanted sideband frequency components, the exemplary JTWPA circuit 100 in FIG. 1 implements the dispersive ground-shunt admittances 112₁, 112₂, 112₃, . . . , 112ᵢ which are configured to add dispersion along the non-linear transmission line to limit the generation of such undesired sideband frequency components and/or suppress (attenuate) the undesired sideband frequency components without disturbing the phase-matching provided by the dispersion elements 120. More specially, the dispersive ground-shunt admittances 112₁, 112₂, 112₃, . . . , 112ᵢ are configured to increase the quantum efficiency and amplification gain by reducing a coupling to higher order sidebands during the frequency mixing process. The dispersive ground-shunt admittances 112₁, 112₂, 112₃, . . . , 112ᵢ are configured to essentially implement a two-mode JTWPA circuit 100 which amplifies the signal and idler frequency bands, and eliminates or otherwise reduces the coupling to higher modes or intermodulation products without impacting the response of the desired signal/idler/pump modes. In the exemplary embodiment of FIG. 1, the dispersion elements 120 are configured to provide dispersion to achieve a desired phase matching in the signal/idler/pump bands, while the dispersive ground-shunt admittances 112₁, 112₂, 112₃, . . . , 112ᵢ are configured to add dispersion to suppress the generation of undesired intermodulation frequency bands. The dispersive ground-shunt admittances 112₁, 112₂, 112₃, . . . , 112ᵢ are configured to not interfere with the phase matching of the dispersion element 120.

In contrast to a conventional JTWPA circuit in which a non-linear transmission line comprises unit cells that each comprise a series Josephson junction and shunt capacitor to ground, the dispersive ground-shunt admittances 112₁, 112₂, 112₃, . . . , 112ᵢ of the exemplary JTWPA circuit 100 of FIG. 1 further include inductors that are configured to cause the dispersive ground-shunt admittances 112₁, 112₂, 112₃, . . . , 112ᵢ to serve as dispersive components in frequency bands of the undesired sideband frequency components to thereby add dispersion along the non-linear transmission line to suppress the generation of the undesired sideband frequency components. The dispersive ground-shunt admittances 112₁, 112₂, 112₃, . . . , 112ᵢ of the exemplary JTWPA circuit 100 are configured to suppress the generation of undesired sideband frequency components by, e.g., one or more of (i) lowering the cutoff frequency of the non-linear transmission line, (ii) increasing the reactance of the non-linear transmission line at the higher order sideband frequencies, and/or (iii) increasing or decreasing the characteristic impedance of the non-linear transmission line at the higher order frequencies of the sideband frequency components, while maintaining a desired characteristic impedance of the non-linear transmission line (e.g., 50 Ohms) for the signal band.

In the exemplary embodiment of the JTWPA circuit 100 of FIG. 1, dispersion engineering is implemented by coupling instances of the dispersion element 120 along the non-linear transmission line according to a desired RPM period to maintain a phase matching and counteract the phase differences between the different modes (e.g., signal mode, pump mode, idler mode) that are propagating in the JTWPA circuit 100, and thereby increase the amplification gain in the signal band. On the other hand, dispersion engineering is implemented via the dispersive ground-shunt admittances 112₁, 112₂, 112₃, . . . , 112ᵢ to prevent phase matching in frequency bands of the higher order modes of the unwanted sideband signals (e.g., harmonics of the pump signal and higher order intermodulation products of the frequency mixing process) to thereby suppress the generation of such unwanted sideband signals.

It is to be understood that FIG. 1 illustrates an exemplary non-limiting embodiment in which the dispersive ground-shunt admittances 112₁, 112₂, 112₃, . . . , 112ᵢ are each implemented using a series-connected capacitive element and inductive element (e.g., lumped capacitor and inductor). However, in other embodiments, the dispersive ground-shunt admittances 112₁, 112₂, 112₃, . . . , 112ᵢ can be implemented using other LC circuit configurations which are suitable to achieve the desired dispersive mode and dispersion functions as discussed herein. For example, in some embodiments, the dispersive ground-shunt admittances 112₁, 112₂, 112₃, . . . , 112ᵢ can be implemented using a parallel connected inductor and capacitor. Moreover, in other embodiments, the inductance of the dispersive ground-shunt admittances 112₁, 112₂, 112₃, . . . , 112ᵢ can be implemented using Josephson junctions.

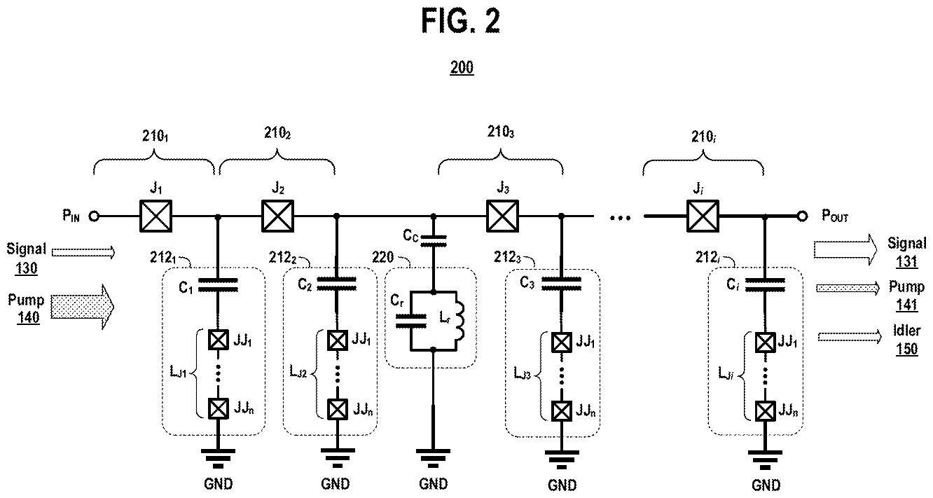

For example, FIG. 2 is a high-level schematic illustration of a Josephson junction traveling-wave parametric circuit, according to an exemplary embodiment of the disclosure. In particular, FIG. 2 schematically illustrates an exemplary architecture of a Josephson traveling-wave parametric amplifier circuit 200 (or JTWPA circuit 200) which is configured to provide dispersive suppression of sideband frequency components (e.g., intermodulation products), according to an exemplary embodiment of the disclosure. The JTWPA circuit 200 comprises an input port P_{IN}, an output port Pour, and a non-linear transmission line comprising a series of unit cells 210₁, 210₂, 210₃, . . . , 210ᵢ (collectively, unit cells 210). Each unit cell 210₁, 210₂, 210₃, . . . , 210ᵢ of the non-linear transmission line comprises a respective Josephson junction J₁, J₂, J₃, . . . , Jᵢ, and a respective admittance 212₁, 212₂, 212₃, . . . , 212ᵢ which is shunted to ground GND (alternatively referred to as dispersive ground-shunt admittances 212₁, 212₂, 212₃, . . . , 212ᵢ). The Josephson junctions J₁, J₂, J₃, . . . , Jᵢ are connected in series between the input port P_{IN} and the output port Pour. In addition, the JTWPA circuit 200 comprises multiple instances of a dispersion element 220 (e.g., dispersion resonator) capacitively coupled to the non-linear transmission line at regular intervals, e.g., a desired RPM) period), to add dispersion for phase matching the propagating signal, pump, and idler modes, as discussed above.

In the exemplary embodiment, each dispersive ground-shunt admittance 212₁, 212₂, 212₃, . . . , 212ᵢ comprises a respective capacitive element C₁, C₂, C₃, . . . , Cᵢ, and a respective inductive element L_{J1}, L_{J2}, L_{J3}, . . . , L_{Ji}. As schematically shown in FIG. 2, each inductive element L_{J1}, L_{J2}, L_{J3}, . . . , L_{Ji} comprises a plurality of series-connected Josephson junctions, J_{J1}, . . . , J_{Jn}. As compared to the exemplary embodiment of FIG. 1 in which each dispersive ground-shunt admittance 112₁, 112₂, 112₃, . . . , 112ᵢ implements a lumped inductive element, the dispersive ground-shunt admittance 212₁, 212₂, 212₃, . . . , 212; in FIG. 2 are each implemented using respective series-connected Josephson junctions, J_{J1}, . . . , J_{Jn} to provide the inductance (Josephson inductance) to realize a dispersive mode at higher frequency bands of the sideband frequency components, and thereby add dispersion along the non-linear transmission line to cause suppression of undesired sideband frequency components including, e.g., unwanted higher order harmonics of a pump signal and higher order intermodulation components, etc. The use of the series-connected Josephson junctions, J_{J1}, . . . , J_{Jn} for implementing the dispersive ground-shunt admittances 212₁, 212₂, 212₃, . . . , 212ᵢ provides a more compact JTWPA unit cell 210 and thus a more overall compact JTWPA circuit 200 (e.g., less footprint area) as compared to utilizing lumped inductors.

The exemplary JTWPA circuit 200 operates in the same or similar manner as the JTWPA circuit 100 of FIG. 1, as discussed above, the details of which need not be repeated. The JTWPA circuit 200 implements dispersion engineering by coupling instances of the dispersion element 220 along the non-linear transmission line according to a desired RPM period to maintain a phase matching and counteract the phase differences between the different modes (e.g., signal mode, pump mode, idler mode) that are propagating in the JTWPA circuit 200, and thereby increase the amplification gain in the signal band. On the other hand, the dispersion engineering is implemented via the dispersive ground-shunt admittances 212₁, 212₂, 212₃, . . . , 212ᵢ to prevent phase matching in frequency bands of the higher order modes of the unwanted sideband signals (e.g., harmonics of the pump signal and higher order intermodulation products of the frequency mixing process) to thereby suppress the generation of such unwanted sideband signals.

It is to be noted that while exemplary embodiments are discussed in the context of JTWPA circuits, the same or similar techniques (as discussed herein) can be utilized to add dispersion to a non-linear transmission line of a Josephson traveling-wave frequency converter circuit to suppress the generation of sideband frequency components as a result of the parametric frequency conversion process. For example, a Josephson traveling-wave frequency converter circuit can be configured with architecture that is substantially the same as the exemplary architecture of the JTWPA circuit of FIG. 1 or 2, but with slight parameter changes and a different pump frequency that is selected to enable frequency conversion, e.g., convert an input signal frequency to an output idler frequency. For example, a Josephson traveling-wave frequency converter circuit can be configured to perform four-wave mixing where the frequency fₛ of the input pump signal (e.g., pump signal 140, FIG. 1) and the frequency fᵢ of the idler signal (e.g., idler signal 150, FIG. 1) have the following relation: fᵢ=2·fₚ+fₛ, which is slightly different from frequency relationship fᵢ=2·fₚ−fₛ of the JTWPA circuit 100 or 200.

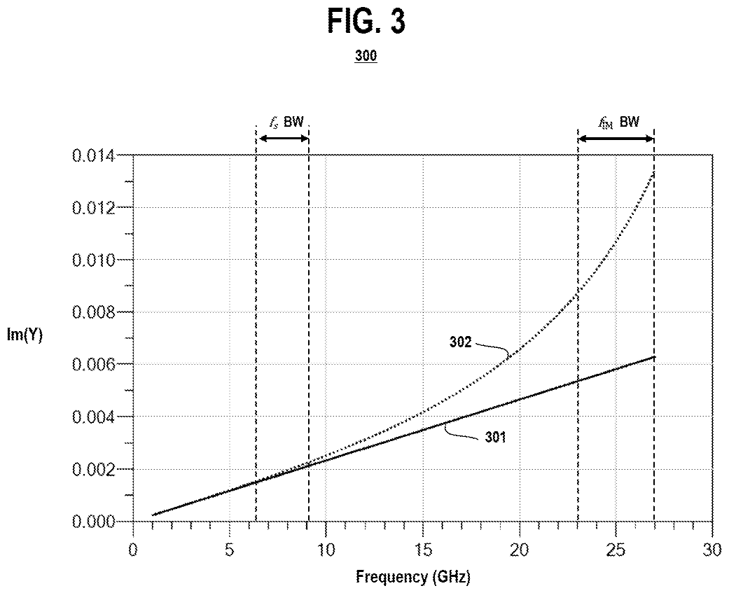

As noted above, a conventional JTWPA circuit comprises, e.g., a non-linear transmission line with unit cells that each comprise a series Josephson junction and shunt capacitor to ground, which can result in the generation of unwanted sideband frequency components as a result of the frequency mixing process (e.g., 4-wave mixing process) which amplifies the input signal, wherein the undesired sideband frequency components are sources of quantum noise that degrade the quantum efficiency of the JTWPA circuit. To illustrate a difference between a conventional JTWPA circuit having unit cells which do not implement dispersive ground-shunt admittances and the exemplary JTWPA circuits which implement unit cells with dispersive ground-shunt admittances for sideband suppression, FIG. 3 depicts simulated admittances of Josephson junction travelling-wave parametric circuits with and without the use of dispersive ground-shunt admittances in unit cells to suppress unwanted sideband frequency components, according to an exemplary embodiment of the disclosure.

In particular, FIG. 3 is a graph 300 which depicts a first plot 301 and a second plot 302 of imaginary components (Im(Y)) of shunt admittances (y-axis) as a function of frequency in GHz (x-axis). The first plot 301 illustrates the susceptance (i.e., the imaginary component of admittance) of a shunt capacitor of a unit cell of a conventional JTWPA circuit in which the unit cell only comprises a shunt capacitor to ground. On the other hand, the second plot 302 illustrates the susceptance (i.e., the imaginary component of admittance) of a shunt admittance of unit cell of, e.g., the JTWPA circuit 100 of FIG. 1 in which the unit cell comprises a dispersive ground-shunt admittance which includes a series-connected capacitive element and inductive element. In addition, FIG. 3 illustrates an exemplary signal frequency bandwidth, fₛBW, in a range of about 6.5 GHz to about 9.25 GHZ, and an exemplary intermodulation frequency band, f_{IM} BW, in a range of about 23.0 GHz to about 27.0 GHz.

As illustrated in FIG. 3, the first plot 301 and the second plot 302 show that in the signal frequency bandwidth, fₛBW, the dispersive ground-shunt admittance of a unit cell (second plot 302) comprising a series-connected capacitor and inductor of the JTWPA circuit 100 of FIG. 1 has an admittance which is similar to an admittance of a unit cell (first plot 301) comprising only a shunt capacitor. In addition, FIG. 3 illustrates that in the intermodulation product frequency band f_{IM} BW, the dispersive ground-shunt admittance of the unit cell (second plot 302) comprising the series-connected capacitor and inductor of the JTWPA circuit 100 of FIG. 1 has an admittance which is different from the admittance of the unit cell (first plot 301) comprising only a shunt capacitor.

In particular, the first plot 301 shows that for a unit cell comprising only a shunt capacitor, the imaginary part of the admittance of the unit cell provides a linear response, wherein the linear response contributes to undesired phase matching for unwanted sideband frequency component (e.g., higher intermodulation component frequencies). On the other hand, the second plot 302 shows that for a unit cell comprising a dispersive ground-shunt admittance comprising a series-connected capacitor and inductor, the imaginary part of the admittance of the unit cell provides a non-linear response wherein the imaginary part of the admittance exponentially increases with frequency. This exponential increase in the admittance changes the reactance of the non-linear transmission line of the JTWPA circuit 100, which results in added dispersion which prevent phase matching of the signal, pump, and idler modes in the intermodulation frequency band f_{IM} BW.

For example, assume a pump signal with a frequency fₚ≈8.25 GHz is utilized to amplify an input signal with a frequency fₛ≈7.0 GHZ. As a result of the frequency mixing process (e.g., 4 wave mixing process), the JTWPA circuits would generate an idler signal with a frequency fᵢ≈9.50 GHz. In addition, the conventional JTWPA circuit with no dispersive ground-shunt admittances would generate sideband frequency components including, e.g., a third harmonic 3fₚ of the pump frequency (3fₚ≈24.75 GHZ), and higher order intermodulation products, such as f_{IM}3=2fₚ+fₛ and f_{IM5}=4fₚ−fₛ, where f_{IM3}≈24.75 GHZ and f_{IM5}≈26.0 GHZ. In a conventional JTWPA circuit with no dispersive ground-shunt admittances, the output power of the unwanted sideband frequency components may be comparable to the output power of the output signal, pump, and idler signals, which is undesirable, as it reduces the quantum efficiency of the JTWPA circuit. However, the second plot 302 in FIG. 3 shows that for a JTWPA circuit having unit cells with dispersive ground-shunt admittances comprising a series-connected capacitor and inductor, the imaginary part of the admittance of the unit cells provides a non-linear response wherein the imaginary part of the admittance exponentially increases with frequency, which results in suppression of the third harmonic 3fₚ of the pump frequency (3fₚ≈24.75 GHZ), and the higher order intermodulation products f_{IM3}≈24.75 GHZ and f_{IM5}≈26.0 GHz in the intermodulation frequency band f_{IM} BW.

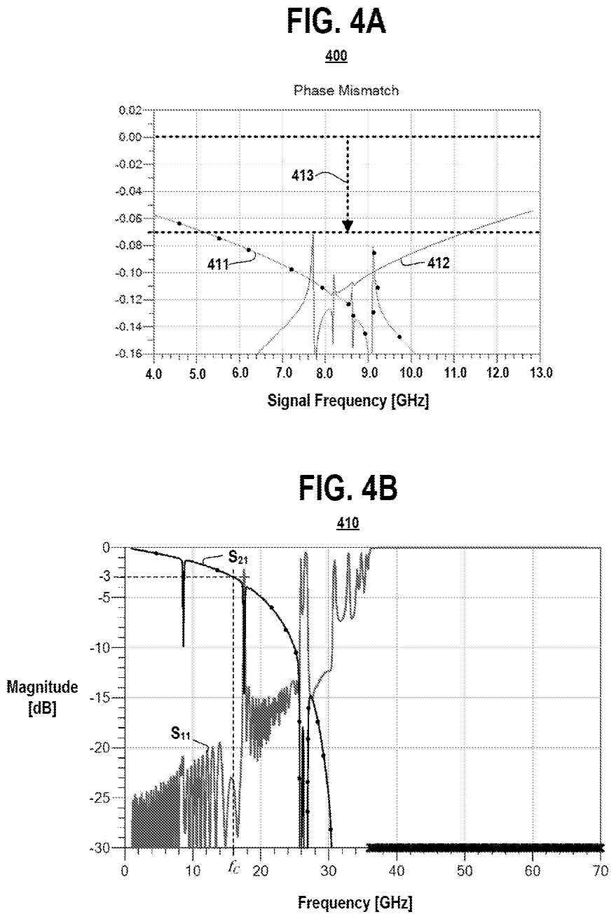

Next, FIG. 4A illustrates phase mismatching of sideband frequency components which results from implementing dispersive ground-shunt admittances that provide dispersive modes for suppressing sideband frequency components, according to an exemplary embodiment of the disclosure. particular, FIG. 4A depicts a simulated phase mismatch 400 for higher order intermodulation components as a function of frequency in GHz. FIG. 4A illustrates a first waveform 411 which represents an amount of phase mismatch (y-axis) of a third order intermodulation product, Δk_{IM3}. In addition, FIG. 4A illustrates a second waveform 412 which represents an amount of phase mismatch (y-axis) of a fifth order intermodulation product, Δk_{IM5}.

As noted above, in an exemplary embodiment, the third order intermodulation product is computed as f_{IM3}=2fₚ+fₛ, and the fifth order intermodulation product is computed as f_{IM5}=4fₚ−fₛ. In addition, as noted above, kₚ denotes an angular wave vector of the pump mode, kₛ denotes an angular wave vector of the signal mode, and kᵢ denotes an angular wave vector of the signal mode. In FIG. 4A, the phase mismatch Δk_{IM3} of the third order intermodulation product is computed as Δk_{IM3}=2kₚ+kₛ−k_{IM3}. Furthermore, the phase mismatch Δk_{IM5} of the fifth order intermodulation product is computed as Δk_{IM5}=2kₚ+kᵢ−k_{IM5}.

In a conventional JTWPA circuit in which each unit cell only comprises a shunt capacitor to ground, the unit cell does not provide dispersion for suppression of the sideband frequency components and as such, the dispersion resonators that are configured for phase matching the signal, pump, and idler modes can result is phase matching the higher order intermodulation component such Δk_{IM3}=0, and Δk_{IM5}=0. On the other hand, in an exemplary JTWPA circuit in which the unit cells comprise a dispersive ground-shunt admittance comprising, e.g., a series-connected capacitor and inductor, the dispersive ground-shunt admittances provide dispersive modes for suppressing the sideband frequency components by, e.g., shifting the amount of phase matching away from zero (0), as indicated by the dashed arrow 413 in FIG. 4A. The first and second waveforms 411 and 412 in FIG. 4A show that the dispersion provided by the dispersive ground-shunt admittances of the unit cells (which comprise a series-connected capacitor and inductor) results in a non-zero phase mismatch for the higher order intermodulation component in the signal frequency bandwidth wherein the amount of phase mismatch |Δk_{IM3}| and |Δk_{IM5}| is 0.07 or greater, which can be sufficient to suppress the generation of such higher order intermodulation components.

Next, FIG. 4B illustrates simulated scattering parameter waveforms of a Josephson junction traveling-wave parametric amplifier circuit which implements dispersive ground-shunt admittances for suppressing sideband frequency components, according to an exemplary embodiment of the disclosure. In particular, FIG. 4B depicts simulated scattering parameter waveforms 410 in terms of power in dB (y-axis) as a function of frequency in GHz (x-axis), wherein such waveforms include a simulated S₂₁ waveform and a simulated Su waveform, for an exemplary JTWPA circuit 100 such as shown in FIG. 1. For example, the S₂₁ waveform represents a transmission coefficient with regard to the transmission of power from a first port (input port P_{IN}) to a second port (output port POUT) of the JTWPA circuit 100. The Su waveform represents a reflection coefficient which is a measure of how much power is reflected at the input port P_{IN} when a signal is applied to the input port P_{IN}.

The S₂₁ waveform illustrates that the exemplary JTWPA circuit 100 with dispersive ground-shunt admittances can be configured to have a cutoff frequency (denoted fc) at a −3 dB point, which is below 20 GHz, wherein such cutoff frequency prevents the generation and output of higher order intermodulation components. The dispersive ground-shunt admittances can be configured to add dispersion to the non-linear transmission line of the JTWPA circuit 100 by, e.g., lowering the cutoff frequency of the non-linear transmission line. In some embodiments, the cutoff frequency is configured to be the frequencies of undesired sidebands to prevent narrowband degradation of the JTWPA, but strong enough to introduce significant dispersion at these frequencies.

To minimize the amount of reflection (S₁₁) at the input port P_{IN} in the signal band, the impedance matching of the non-linear transmission line can be properly maintained by a proper choice of parameters of the capacitor and inductors of the dispersive ground-shunt admittances. In some embodiments, the capacitance values of the dispersive ground-shunt admittances of the exemplary JTWPA circuits 100 and 200 as shown in FIGS. 1 and 2 can be the same or similar to those of conventional JTWPA circuits in which each unit cell implements a shunt capacitor, while the inductance value of the inductors can be selected to ensure proper impedance matching and set a cutoff frequency. In the exemplary embodiments, the values of the LC components of the dispersive ground-shunt admittances are selected so dispersive ground-shunt admittances behave more like a capacitor in the signal frequency band, while the dispersive ground-shunt admittances behave more like an inductor at higher frequencies to provide the dispersion that is needed to suppress higher order modes of unwanted sideband frequencies.

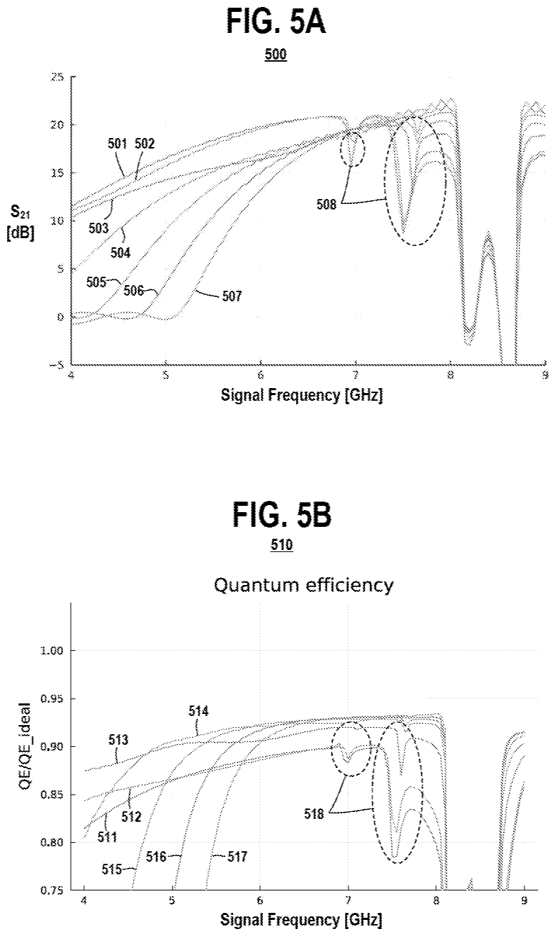

Next, FIG. 5A illustrates simulated signal gain waveforms of a Josephson junction traveling-wave parametric amplifier circuit which implements dispersive ground-shunt admittances for suppressing sideband frequency components, according to an exemplary embodiment of the disclosure. In particular, FIG. 5A illustrates simulated signal gain waveforms 500 showing gain in dB (y-axis) as a function of frequency in GHz (x-axis) for different values of inductors used to implement dispersive ground-shunt admittances of, e.g., the exemplary JTWPA circuit 100 of FIG. 1, in which the dispersive ground-shunt admittances are each implemented with a series-connected capacitive element and inductive element.

In FIG. 5A, the simulated signal gain waveforms 500 include signal waveforms 501, 502, 503, 504, 505, 506, and 507, which depict different signal gain profiles of an exemplary JTWPA circuit 100 in which the dispersive ground-shunt admittances are each implemented with inductive elements having an inductance value of 1.0 picohenry (pH) (waveform 501), 10.0 pH (waveform 502), 100 pH (waveform 503), 200 pH (waveform 504), 300 pH (waveform 505), 400 pH (waveform 506), and 500 pH (waveform 507). FIG. 5A illustrates that as the size of the dispersion inductor is increased, the gain ripples due to higher order sidebands become increasing smaller and essentially disappear. In FIG. 5A, the gain ripples comprise the portions 508 of the simulated signal gain waveforms 500, which are included within dashed-line oval outlines. Further, FIG. 5A shows that high gain is maintained in a target BW region of about 6 GHz to about 8 GHZ.

Next FIG. 5B illustrates simulated plots of quantum efficiency of a Josephson junction traveling-wave parametric amplifier circuit which implements dispersive ground-shunt admittances for suppressing sideband frequency components, according to an exemplary embodiment of the disclosure. In particular, FIG. 5B illustrates simulated plots 510 of quantum efficiency QE (normalized by an ideal quantum efficiency QE_ideal) (y-axis) as a function of frequency in GHz (x-axis) for different values of inductors used to implement dispersive ground-shunt admittances of, e.g., the exemplary JTWPA circuit 100 of FIG. 1, in which the dispersive ground-shunt admittances are each implemented with a series-connected capacitive element and inductive element.

In FIG. 5B, the simulated plots 510 of QE include QE plots 511, 512, 513, 514, 515, 516, and 517, which depict different QE profiles of the exemplary JTWPA circuit 100 in which the dispersive ground-shunt admittances are each implemented with inductive elements having an inductance value of 1.0 pH (QE plot 511), 10.0 pH (QE plot 512), 100 pH (QE plot 513), 200 pH (QE plot 514), 300 pH (QE plot 515), 400 pH (QE plot 516), and 500 pH (QE plot 517). FIG. 5B illustrates that as the size of the dispersion inductor is increased and the gain ripples (in FIG. 5A) due to higher order sidebands become increasingly smaller, the ripple portions of the quantum efficiency plots (as included within dashed-line oval outlines 518 of FIG. 5B) become increasingly smaller. In particular, FIG. 5B illustrates that the normalized quantum efficiency consistently improves to above 90% in the target amplifying frequency range (6 GHz to 8 GHZ) for, e.g., the simulated QE plots 514, 515, 516, and 517.

It is to be appreciated that the implementation of unit cells with dispersive ground-shunt admittances to suppress the generation of sideband frequency components provides significant advantages over other sideband suppression techniques. For example, similar to using the discrete dispersion resonator elements (e.g., dispersion elements 120, FIG. 1) for phase matching at the desired signal modes, sideband suppression can be implemented by capacitively coupling discrete sideband suppression resonator elements to the non-linear transmission line every, e.g., 10 unit cells. These discrete sideband suppression resonator elements can be configured to have resonant frequencies that correspond to frequencies of the higher sideband modes, e.g., the third harmonic of the pump frequency 3fₚ and higher order intermodulation products such as f_{IM3}=2fₚ+fₛ and f_{IM5}=4fₚ−fₛ, etc.

There are disadvantages, however, to utilizing discrete sideband suppression resonators to create desired stopbands to suppress sideband frequencies components. For example, the discrete sideband suppression resonators increase the footprint of the JTWPA circuit. Moreover, the capacitive coupling of the discrete sideband suppression resonators to the non-linear transmission line of the JTWPA circuit results in a narrow band response (e.g., narrow stop band response) for attenuating the sideband frequency components. In contrast, the implementation of unit cells with dispersive ground-shunt admittances allows for direct coupling of the dispersive ground-shunt admittances to the non-linear transmission line, which results in a more broadband suppression of the sideband frequency components. For example, FIG. 1 shows a direct coupling of the dispersive ground-shunt admittances 112₁, 112₂, 112₃, . . . , 112ᵢ (with series L and C components) to the nonlinear transmission line of the JTWPA circuit 100, which yields a broadband suppression of sideband frequency components, such as shown in FIG. 4B. Moreover, the addition of the inductive elements in the dispersive ground-shunt admittances 112₁, 112₂, 112₃, . . . , 112ᵢ provide advantages of (i) enabling a more compact design as compared to capacitively coupling discrete sideband suppression resonators to the nonlinear transmission line of the JTWPA circuit, and (ii) yielding a minimal variation in fabrication, as compared to the higher variation associated with the fabrication of discrete sideband suppression resonators when considering fabrication tolerances.

Moreover, other sideband suppression techniques include generating bandgaps/stopbands through impedance modulation of the JTWPA circuit. Such techniques provide a relatively small stopband at an intermodulation band and, thus, are not as effective as utilizing the exemplary dispersive ground-shunt admittance techniques as discussed herein which provide broadband suppression. In addition, the impedance modulation techniques involve varying the Josephson junctions of the transmission lines, which makes the stopbands to be pump power dependent and thus, hard to achieve in practice.

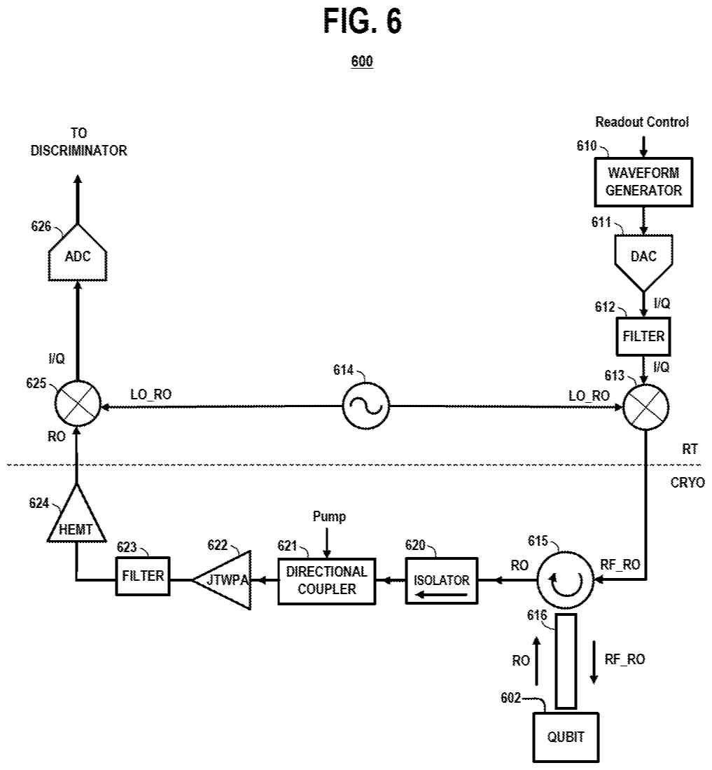

FIG. 6 schematically illustrates readout circuitry of a quantum processing system, which can implement JTWPA circuits in qubit readout signal paths for amplifying qubit readout signals, according to an exemplary embodiment of the disclosure. More specifically, FIG. 6 schematically illustrates qubit readout control circuitry 600 of a quantum computing system which is configured to readout a quantum state of at least one superconducting qubit 602. The qubit readout control circuitry 600 is configured to generate an RF readout control signal (RF_RO) to readout the state of the superconducting qubit 602 using a dispersive readout scheme which enables a quantum non-demolition measurement of the state of the superconducting qubit 602 to preserve the state of the superconducting qubit 602. In an exemplary embodiment, the qubit readout control circuitry 600 receives and processes readout control signals from a control process.

The qubit readout control circuitry 600 comprises a waveform generator 610 (or pulse envelope generator), digital-to-analog (DAC) circuitry 611, low-pass filter circuitry 612, a first I/Q mixer 613 (upconverter mixer), a local oscillator (LO) signal generator 614, a circulator 615, a readout resonator 616, and a readout signal chain which comprises an isolator circuit 620, a directional coupler 621, a JTWPA circuit 622, a filter 623, a high-electron-mobility-transistor (HEMT) amplifier 624, a second I/Q mixer 625, and analog-to-digital converter (ADC) circuitry 626, which outputs digital readout signals to a hardware or software based discriminator to determine a readout state of the superconducting qubit 602.

The waveform generator 610 is configured to generate digital I and Q signals with a given type of pulse envelope (e.g., Gaussian square pulse envelope) for qubit state readout, in response to a readout control signal. The DAC circuitry 611 is configured to convert the digital I and Q pulses into analog I and Q control pulses which are filtered by the low-pass filter circuitry 612. The filtered analog control I and Q control pulses are applied to the first I/Q mixer 613, along with an LO signal (LO_RO) that is generated by the LO signal generator 614, to generate an RF readout control pulse RF_RO. In particular, the I/Q mixer 613 is configured mix the analog I and Q control pulses with the LO_Q signals of a given LO frequency (e.g., 7 GHZ) to perform I/Q modulation and upconversion and/or downconversion using known techniques (e.g., single sideband modulation) to generate the RF readout control pulse RF_RO.

The RF readout control signal RF_RO is applied to an input port of the circulator 615, and then coupled to the readout resonator 616. The readout resonator 616 is capacitively coupled to the superconducting qubit 602, thereby providing a qubit/resonator system. In some embodiments, the readout resonator 616 comprises, e.g., a half-wavelength coplanar waveguide resonator, having a resonant frequency that is the same or similar to a center frequency of the RF readout control signal RF_RO. The resonant frequency of the readout resonator 616 is detuned from the transition frequency of the superconducting qubit 602. In the dispersive regime of qubit-resonator coupling, the RF readout control signal RF_RO (with the requisite frequency tone, pulse envelope shape, and pulse duration) interacts with the given qubit/resonator system in a manner which results in the generation of a resulting readout signal RO that is reflected out from the readout resonator 616, wherein the readout signal RO comprises information (e.g., phase and/or amplitude) that is qubit-state dependent. In other words, the dispersive readout process yields an RF readout signal RO having a state-dependent phasor response, which is analyzed to discriminate the quantum state of the superconducting qubit 602.

In another exemplary configuration, the RF readout control signal RF_RO is applied to an input port of a readout resonator 616 that is coupled to the superconducting qubit 602. The readout signal RO is output from the readout resonator 616 via an output port. The input port of the readout resonator 616 is much more weakly coupled to the readout resonator 616 than the output port so the readout signal RO exits via the output port. Optionally, the output port of the readout resonator 616 can be coupled to a Purcell filter, which is designed to pass at the frequency of the readout signal RO while blocking at the qubit frequency, to enhance the qubit lifetime.

The readout signal RO that is returned from the readout resonator 616 is input to the circulator 615, and then coupled out to the readout signal chain where the readout signal RO flows through the isolator circuit 620 and directional coupler 621 and is applied to an input port of the JTWPA circuit 622. In addition, the directional coupler 621 receives a pump signal (Pump) and couples the pump signal to the input port of the JTWPA circuit 622. The JTWPA circuit 622 amplifies the readout signal RO by, e.g., performing a 4-wave mixing process using the pump signal, as discussed above. In some embodiments, the JTWPA circuit 622 comprises unit cells that implement dispersive ground-shunt admittances for suppressing sideband frequency components, based on exemplary JTWPA circuit architectures of, e.g., FIG. 1 or 2.

The amplified readout signal RO, which is output from the JTWPA circuit 622, is transmitted along a signal chain comprising the filter 623 and another optional isolator circuit, amplified by the HEMT amplifier 624, and applied to an input of the second I/Q mixer 625. The second I/Q mixer 625 mixes the RF readout signal RO with the LO_RO signal to perform a down conversion operation where the RF readout signal RO is down converted and split into analog I and Q signals. The analog I and Q signals are input to the ADC circuitry 626 and sampled by the ADC circuitry 626 to generate respective digital I and Q signals that are indicative of the amplitude and phase of the readout signal RO. A discriminator analyzes the digital I and Q signals to discriminate the measured quantum state of the superconducting qubit 602 based on the amplitude and phase components of the readout signal RO.

It is to be understood that FIG. 6 is an exemplary non-limiting embodiment which schematically illustrates a high-level schematic illustration of readout control circuitry. The qubit readout control circuitry 600 and readout signal chain can be implemented using other components and configurations. For example, a frequency-multiplexed readout system (which implements frequency domain multiplexing) can be utilized to scale-up a readout chain in a quantum computing system for reading the quantum states of superconducting qubits in relatively large superconducting quantum computers. In a frequency-multiplexed readout system, multiple readout resonators (with different resonance frequencies) are coupled to separate qubits and commonly coupled to a communication bus. The communication bus is configured to allow the transmission of multiple readout signals with readout frequencies which match the resonance frequencies of the readout resonators, and, thus simultaneously read out the quantum states of multiple qubits using one input and one output line.

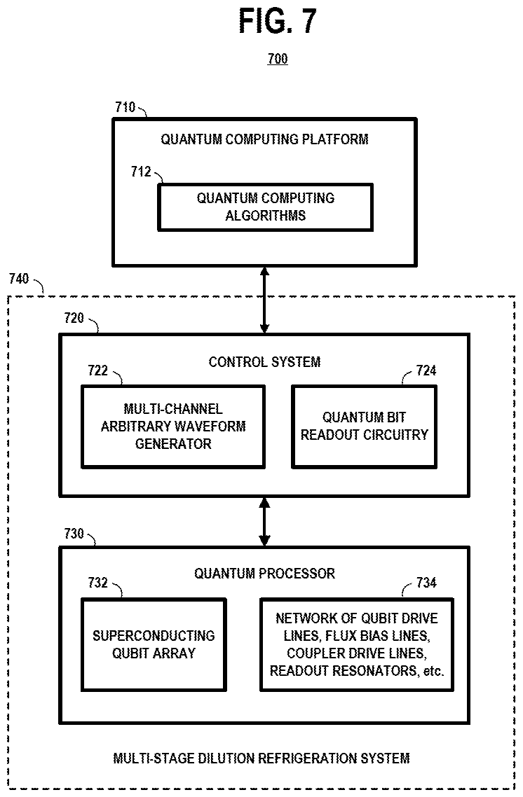

FIG. 7 schematically illustrates a quantum computing system 700 which comprises a quantum computing platform 710, a control system 720, and a quantum processor 730. In some embodiments, the quantum computing platform 710 implements a software platform that is configured to program a quantum computer to execute quantum computing algorithms 712 which are implemented using, e.g., quantum circuits which define computational routings consisting of coherent quantum operations on quantum data, such as qubits. In addition, in some embodiments, the control system 720 comprises a multi-channel arbitrary waveform generator 722, and a quantum bit readout control circuitry 724. The quantum processor 730 comprises one or more solid-state quantum chips which comprise, e.g., a superconducting qubit array 732, and a network 734 of qubit drive lines, flux-bias control lines, qubit coupler drive lines, qubit state readout resonators, and other circuit QED components that may be needed for a given application or quantum system configuration.

In some embodiments, the control system 720 and the quantum processor 730 are disposed in a dilution refrigeration system 740 which can generate cryogenic temperatures that are sufficient to operate components of the control system 720 for quantum computing applications. For example, the quantum processor 730 may need to be cooled down to near-absolute zero, e.g., 10-15 millikelvin (mK), to allow the superconducting qubits to exhibit quantum behaviors. In some embodiments, the dilution refrigeration system 740 comprises a multi-stage dilution refrigerator where the components of the control system 720 can be maintained at different cryogenic temperatures, as needed. For example, while the quantum processor 730 may need to be cooled down to, e.g., 10-15 mK, the circuit components of the control system 720 may be operated at cryogenic temperatures greater than 10-15 mK (e.g., cryogenic temperatures in a range of 3K-4K), depending on the configuration of the quantum computing system. In some embodiments, the entirety of the control system 720, or some components thereof, are disposed in a room temperature environment.

In some embodiments, the superconducting qubit array 732 comprises a quantum system of superconducting qubits, superconducting qubit couplers, and other components commonly utilized to support quantum processing using qubits. The number of superconducting qubits of the superconducting qubit array 732 can be on the order of tens, hundreds, thousands, or more, etc. The network 734 of qubit drive lines, flux bias control lines, coupler drive lines, and qubit state readout resonators, etc., is configured to apply microwave control signals to superconducting qubits and coupler circuitry in the superconducting qubit array 732 to perform various types of gate operations, e.g., single-gate operations, entanglement gate operations, perform error correction operations, etc., as well as read the quantum states of the superconducting qubits. For example, microwave control pulses are applied to the qubit drive lines of respective superconducting qubits to change the quantum state of the superconducting qubits (e.g., change the quantum state of a given qubit between the ground state and excited state, or to a superposition state) when executing quantum information processing algorithms.

Furthermore, as noted above, the state readout lines comprise readout resonators that are coupled to respective superconducting qubits. The state of a given superconducting qubit can be determined through microwave transmission or reflection measurements using the readout ports of the readout resonator. The states of the superconducting qubits are read out after executing a quantum algorithm. In some embodiments, as noted above, a dispersive readout operation is performed in which a change in the resonant frequency of a given readout resonator, which is coupled to a given superconducting qubit, is utilized to readout the state (e.g., ground or excited state) of the given superconducting qubit.

The network 734 of qubit drive lines, flux bias lines, qubit coupler drive lines, qubit state readout resonators, etc., is coupled to the control system 720 through a suitable hardware input/output (I/O) interface, which couples I/O signals between the control system 720 and the quantum processor 730. For example, the hardware I/O interface may comprise various types of hardware and components, such as RF cables, wiring, RF elements, optical fibers, heat exchanges, filters, amplifiers, isolators, etc.

In some embodiments, the multi-channel arbitrary waveform generator (AWG) 722 and other suitable microwave pulse signal generators are configured to generate the microwave control pulses that are applied to the qubit drive lines, and the coupler drive lines to control the operation of the superconducting qubits and associated qubit coupler circuitry, when performing various gate operations to execute a given certain quantum information processing algorithm. In some embodiments, the multi-channel AWG 722 comprises a plurality of AWG channels, which control respective superconducting qubits within the superconducting qubit array 732 of the quantum processor 730. In some embodiments, each AWG channel comprises a baseband signal generator, a digital-to-analog converter (DAC) stage, a filter stage, a modulation stage, an impedance matching network, and a phase-locked loop system to generate LO signals (e.g., quadrature LO signals LO_I and LO_Q) for the respective modulation stages of the respective AWG channels.

In some embodiments, the multi-channel AWG 722 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control a given quantum bit that is coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I (t) and Q (t)) having a baseband frequency. The filter stage for the given AWG channel is configured to filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I (t) and Q (t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal). In some embodiments, the quantum bit readout control circuitry 724 is implemented based on the readout circuit architecture as schematically shown in FIG. 6.

The quantum computing platform 710 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), performing calibration operations to calibrate the quantum circuit elements and gate operations, etc. In addition, the quantum computing platform 710 comprises a hardware architecture of processors, memory, etc., which is configured to control the execution of quantum applications, and interface with the control system 720 to (i) generate digital control signals that are converted to analog microwave control signals by the control system 720, to control operations of the quantum processor 730 when executing a given quantum application, and (ii) to obtain and process digital signals received from the control system 720, which represent the processing results generated by the quantum processor 730 when executing various gate operations for a given quantum application.

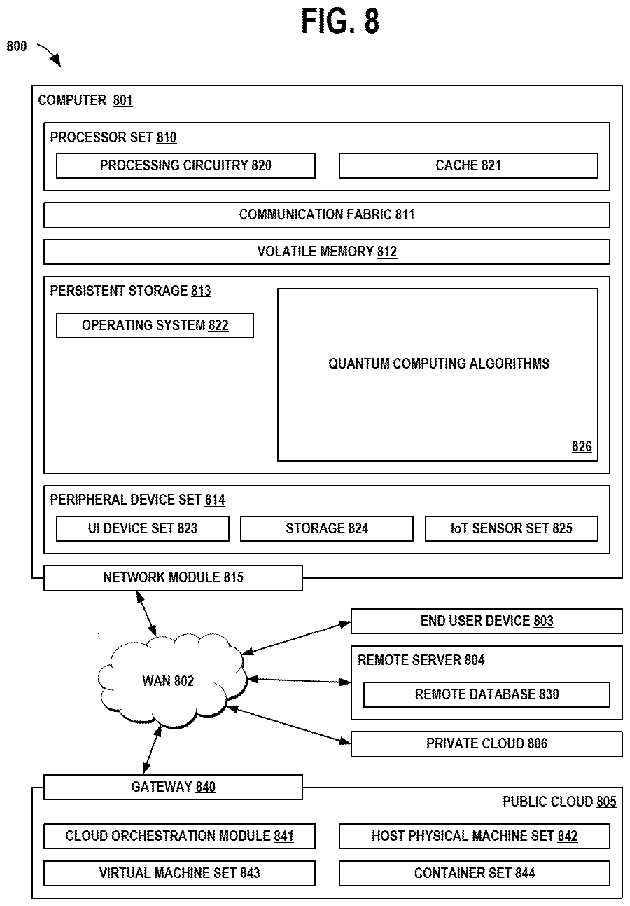

In some exemplary embodiments, the quantum computing platform 710 of the quantum computing system 700 may be implemented using any suitable computing system architecture (e.g., as shown in FIG. 8) which is configured to implement methods to support quantum computing operations by executing computer readable program instructions that are embodied on a computer program product which includes a computer readable storage medium (or media) having such computer readable program instructions thereon for causing a processor to perform control methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 800 of FIG. 8 contains an example of an environment for the execution of at least some of the computer code (block 826) involved in executing quantum computing algorithms (e.g., quantum computing algorithms 712, FIG. 7). In addition to block 826, computing environment 800 includes, for example, computer 801, wide area network (WAN) 802, end user device (EUD) 803, remote server 804, public cloud 805, and private cloud 806. In this embodiment, computer 801 includes processor set 810 (including processing circuitry 820 and cache 821), communication fabric 811, volatile memory 812, persistent storage 813 (including operating system 822 and block 826, as identified above), peripheral device set 814 (including user interface (UI), device set 823, storage 824, and Internet of Things (IoT) sensor set 825), and network module 815. Remote server 804 includes remote database 830. Public cloud 805 includes gateway 840, cloud orchestration module 841, host physical machine set 842, virtual machine set 843, and container set 844.

Computer 801 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 830. As is well understood in the art of computer technology, and depending upon the technology, performance of a computer-implemented method may be distributed among multiple computers and/or between multiple locations. On the other hand, in this presentation of computing environment 800, detailed discussion is focused on a single computer, specifically computer 801, to keep the presentation as simple as possible. Computer 801 may be located in a cloud, even though it is not shown in a cloud in FIG. 8. On the other hand, computer 801 is not required to be in a cloud except to any extent as may be affirmatively indicated.

Processor set 810 includes one, or more, computer processors of any type now known or to be developed in the future. Processing circuitry 820 may be distributed over multiple packages, for example, multiple, coordinated integrated circuit chips. Processing circuitry 820 may implement multiple processor threads and/or multiple processor cores. Cache 821 is memory that is located in the processor chip package(s) and is typically used for data or code that should be available for rapid access by the threads or cores running on processor set 810. Cache memories are typically organized into multiple levels depending upon relative proximity to the processing circuitry. Alternatively, some, or all, of the cache for the processor set may be located “off chip.” In some computing environments, processor set 810 may be designed for working with qubits and performing quantum computing.

Computer readable program instructions are typically loaded onto computer 801 to cause a series of operational steps to be performed by processor set 810 of computer 801 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 821 and the other storage media discussed below. The program instructions, and associated data, are accessed by processor set 810 to control and direct performance of the inventive methods. In computing environment 800, at least some of the instructions for performing the inventive methods may be stored in block 826 in persistent storage 813.

Communication fabric 811 is the signal conduction path that allow the various components of computer 801 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 812 is any type of volatile memory now known or to be developed in the future. Examples include dynamic type random access memory (RAM) or static type RAM. Typically, the volatile memory is characterized by random access, but this is not required unless affirmatively indicated. In computer 801, the volatile memory 812 is located in a single package and is internal to computer 801, but, alternatively or additionally, the volatile memory may be distributed over multiple packages and/or located externally with respect to computer 801.

Persistent storage 813 is any form of non-volatile storage for computers that is now known or to be developed in the future. The non-volatility of this storage means that the stored data is maintained regardless of whether power is being supplied to computer 801 and/or directly to persistent storage 813. Persistent storage 813 may be a read only memory (ROM), but typically at least a portion of the persistent storage allows writing of data, deletion of data and re-writing of data. Some familiar forms of persistent storage include magnetic disks and solid-state storage devices. Operating system 822 may take several forms, such as various known proprietary operating systems or open source Portable Operating System Interface type operating systems that employ a kernel. The code included in block 826 typically includes at least some of the computer code involved in performing the inventive methods.

Peripheral device set 814 includes the set of peripheral devices of computer 801. Data communication connections between the peripheral devices and the other components of computer 801 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 823 may include components such as a display screen, speaker, microphone, wearable devices (such as goggles and smart watches), keyboard, mouse, printer, touchpad, game controllers, and haptic devices. Storage 824 is external storage, such as an external hard drive, or insertable storage, such as an SD card. Storage 824 may be persistent and/or volatile. In some embodiments, storage 824 may take the form of a quantum computing storage device for storing data in the form of qubits. In embodiments where computer 801 is required to have a large amount of storage (for example, where computer 801 locally stores and manages a large database) then this storage may be provided by peripheral storage devices designed for storing very large amounts of data, such as a storage area network (SAN) that is shared by multiple, geographically distributed computers. IoT sensor set 825 is made up of sensors that can be used in Internet of Things applications. For example, one sensor may be a thermometer and another sensor may be a motion detector.

Network module 815 is the collection of computer software, hardware, and firmware that allows computer 801 to communicate with other computers through WAN 802. Network module 815 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 815 are performed on the same physical hardware device. In other embodiments (for example, embodiments that utilize software-defined networking (SDN)), the control functions and the forwarding functions of network module 815 are performed on physically separate devices, such that the control functions manage several different network hardware devices. Computer readable program instructions for performing the inventive methods can typically be downloaded to computer 801 from an external computer or external storage device through a network adapter card or network interface included in network module 815.

WAN 802 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 803 is any computer system that is used and controlled by an end user (for example, a customer of an enterprise that operates computer 801), and may take any of the forms discussed above in connection with computer 801. EUD 803 typically receives helpful and useful data from the operations of computer 801. For example, in a hypothetical case where computer 801 is designed to provide a recommendation to an end user, this recommendation would typically be communicated from network module 815 of computer 801 through WAN 802 to EUD 803. In this way, EUD 803 can display, or otherwise present, the recommendation to an end user. In some embodiments, EUD 803 may be a client device, such as thin client, heavy client, mainframe computer, desktop computer and so on.

Remote server 804 is any computer system that serves at least some data and/or functionality to computer 801. Remote server 804 may be controlled and used by the same entity that operates computer 801. Remote server 804 represents the machine(s) that collect and store helpful and useful data for use by other computers, such as computer 801. For example, in a hypothetical case where computer 801 is designed and programmed to provide a recommendation based on historical data, then this historical data may be provided to computer 801 from remote database 830 of remote server 804.

Public cloud 805 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 805 is performed by the computer hardware and/or software of cloud orchestration module 841. The computing resources provided by public cloud 805 are typically implemented by virtual computing environments that run on various computers making up the computers of host physical machine set 842, which is the universe of physical computers in and/or available to public cloud 805. The virtual computing environments (VCEs) typically take the form of virtual machines from virtual machine set 843 and/or containers from container set 844. It is understood that these VCEs may be stored as images and may be transferred among and between the various physical machine hosts, either as images or after instantiation of the VCE. Cloud orchestration module 841 manages the transfer and storage of images, deploys new instantiations of VCEs and manages active instantiations of VCE deployments. Gateway 840 is the collection of computer software, hardware, and firmware that allows public cloud 805 to communicate through WAN 802.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 806 is similar to public cloud 805, except that the computing resources are only available for use by a single enterprise. While private cloud 806 is depicted as being in communication with WAN 802, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 805 and private cloud 806 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a Josephson junction traveling-wave parametric circuit comprising unit cells which are coupled in series to form a transmission line between an input port and an output port, each unit cell comprising a series Josephson junction, and a dispersive ground-shunt admittance configured to cause suppression of one or more sideband frequency components.

2. The device of claim 1, wherein the Josephson junction traveling-wave parametric circuit comprises a Josephson traveling-wave frequency converter circuit.

3. The device of claim 1, wherein the Josephson junction traveling-wave parametric circuit comprises a Josephson traveling-wave parametric amplifier circuit.

4. The device of claim 1, wherein the dispersive ground-shunt admittance of each unit cell comprises a capacitive element and an inductive element.

5. The device of claim 4, wherein the inductive element is configured to add the dispersion along the transmission line to cause the suppression of the one or more sideband frequency components.

6. The device of claim 4, wherein the capacitive element and the inductive element comprise a series-connected capacitor and inductor.

7. The device of claim 4, wherein the inductive element comprises a plurality of series-connected Josephson junctions.

8. The device of claim 1, wherein the dispersive ground-shunt admittances of the unit cells are configured to add dispersion along the transmission line to cause the suppression of sideband frequency components resulting from intermodulation between frequency components of a pump signal and an input signal.

9. The device of claim 1, wherein the Josephson junction traveling-wave parametric circuit further comprises dispersion resonators which are capacitively coupled to the transmission line and which are configured to maintain phase matching between different signal modes that are propagating along the transmission line.

10. A device, comprising:
a Josephson traveling-wave parametric amplifier circuit that is configured to amplify a readout signal representing a state of at least one quantum bit;
wherein the Josephson traveling-wave parametric amplifier circuit comprises unit cells which are coupled in series to form a transmission line between an input port and an output port, each unit cell comprising a series Josephson junction, and a dispersive ground-shunt admittance configured to cause suppression of one or more sideband frequency components resulting from intermodulation between frequency components of the readout signal and a pump signal applied to the input port of the Josephson traveling-wave parametric amplifier circuit.

11. The device of claim 10, wherein the dispersive ground-shunt admittance of each unit cell of the Josephson traveling-wave parametric amplifier circuit comprises a capacitive element and an inductive element.

12. The device of claim 11, wherein the inductive element is configured to add the dispersion along the transmission line to cause the suppression of the one or more sideband frequency components.

13. The device of claim 11, wherein the capacitive element and the inductive element comprise a series-connected capacitor and inductor.

14. The device of claim 11, wherein the inductive element comprises a plurality of series-connected Josephson junctions.

15. The device of claim 10, wherein the Josephson traveling-wave parametric amplifier circuit further comprises dispersion resonators which are capacitively coupled to the transmission line and which are configured to maintain phase matching between different signal modes of the readout signal and the pump signal that are propagating along the transmission line.

16. A system, comprising:
a quantum processor comprising quantum bits; and
readout circuitry comprising at least one readout signal chain comprising a Josephson traveling-wave parametric amplifier circuit that is configured to amplify a readout signal representing a state of at least one quantum bit of the quantum processor;
wherein the Josephson traveling-wave parametric amplifier circuit comprises unit cells which are coupled in series to form a transmission line between an input port and an output port, each unit cell comprising a series Josephson junction, and a dispersive ground-shunt admittance configured to cause suppression of one or more sideband frequency components resulting from intermodulation between frequency components of the readout signal and a pump signal applied to the input port of the Josephson traveling-wave parametric amplifier circuit.

17. The system of claim 16, wherein:
the dispersive ground-shunt admittance of each unit cell of the Josephson traveling-wave parametric amplifier circuit comprises a capacitive element and an inductive element; and
the inductive element is configured to add the dispersion along the transmission line to cause the suppression of the one or more sideband frequency components.

18. The system of claim 17, wherein the capacitive element and the inductive element comprise a series-connected capacitor and inductor.

19. The system of claim 17, wherein the inductive element comprises a plurality of series-connected Josephson junctions.

20. The system of claim 16, wherein the Josephson traveling-wave parametric amplifier circuit further comprises dispersion resonators which are capacitively coupled to the transmission line and which are configured to maintain phase matching between different signal modes of the readout signal and the pump signal that are propagating along the transmission line.
